(19) United States
(12) Patent Application Publication
(10) Pub. No.: US 2005/0001214 A1
(43) Pub. Date: Jan. 6, 2005

(54) Micro- or nano-electronic component comprising a power source and means for protecting the power source

(76) Inventors: Jean Brun, Champagnier (FR); Raphael Salot, Lans En Vercors (FR); Gilles Poupon, Seyssinet-Pariset (FR); Helene Rouault, Le Bersoud (FR)

Correspondence Address: OLIFF & BERRIDGE, PLC, P.O. BOX 19928, ALEXANDRIA, VA, 22320, US

(21) Appl. No.: 10/492,048

(22) PCT Filed: Oct. 21, 2002
(86) PCT No.: PCT/FR02/03589

(30) Foreign Application Priority Data
Oct. 22, 2001 (FR) 01/13569

(51) Int. Cl. H01L 29/04

(52) U.S. Cl. 257/59

(57) ABSTRACT

The component comprises a sealed cavity wherein the unprotected power source formed by a micro-battery or a micro-supercapacitance is deposited. Any penetration of the ambient atmosphere into the sealed cavity causes destruction of the power source by oxidation, thereby making the component inoperative. The cavity can be in a vacuum or filled with an inert gas. A pressure sensor can be fitted inside the cavity and detect a pressure variation inside the cavity to make the component inoperative when the pressure variation exceeds a predetermined threshold. The cavity can be closed by a cover or filled with a filling material consisting of silicone resin, thermosetting resin, polymer, epoxy, fusible glass or a metal chosen from indium, tin, lead or alloys thereof.

### BACKGROUND OF THE INVENTION

The invention relates to a micro- or nano-electronic component comprising a power source in the form of thin films deposited on a substrate and means for protecting the power source against the ambient atmosphere.

### STATE OF THE ART

Power sources in the form of thin films deposited on a substrate comprise elements which react with the ambient atmosphere, and are able to cause rapid deterioration of the power source. The metallic lithium constituting the negative electrode of a micro-battery for example oxidizes quickly in contact with air, in particular in the presence of humidity. It is therefore indispensable to protect these power sources from the ambient air by an efficient protection compatible with their use in micro-electronics.

U.S. Pat. No. 5,561,004 describes a lithium battery in the form of thin films protected from the outside atmosphere by at least one additional layer. The protective layers are deposited in the form of thin films directly on the lithium electrode of the battery so as to totally cover the exposed parts of this electrode. The materials used to form these protective layers are metal, ceramic, a ceramic-metal combination, a parylene-metal combination, a parylene-ceramic combination or a parylene-ceramic-metal combination. This type of coating provides chemical protection of the battery but does not provide protection against an intrusion of mechanical type.

### OBJECT OF THE INVENTION

The object of the invention is to improve the security of a micro- or nano-electronic component comprising a power source formed on a substrate.

According to the invention, this objective is achieved by a component according to the appended claims, and more particularly by the fact that the protection means comprise a sealed cavity wherein the unprotected power source is arranged, any penetration of the ambient atmosphere into the sealed cavity causing destruction of the power source, by oxidation, thereby making the component inoperative.

The cavity can be in a vacuum or filled with an inert gas.

According to a development of the invention, the component comprises a pressure sensor arranged inside the cavity and detecting a pressure variation inside the cavity to make the component inoperative when the pressure variation exceeds a predetermined threshold.

According to another development, the cavity is filled with a filling material consisting of silicone resin, thermosetting resin, polymer, fusible glass or a metal chosen from indium, tin, lead or alloys thereof.

The power source can be formed by a micro-battery or a micro-supercapacitance.

### BRIEF DESCRIPTION OF THE DRAWINGS

Other advantages and features will become more clearly apparent from the following description of particular embodiments of the invention given as non-restrictive examples only and represented in the accompanying drawings, in which:

FIG. 1 represents a first embodiment of a component according to the invention.

FIG. 2 illustrates a second embodiment of a component according to the invention, before the cavity is closed.

FIG. 3 represents a particular embodiment of closing of the cavity of a component according to FIG. 2.

FIG. 4 represents a micro-supercapacitance able to constitute the power source.

FIG. 5 illustrates a particular embodiment of making the component inoperative.

### DESCRIPTION OF PARTICULAR EMBODIMENTS

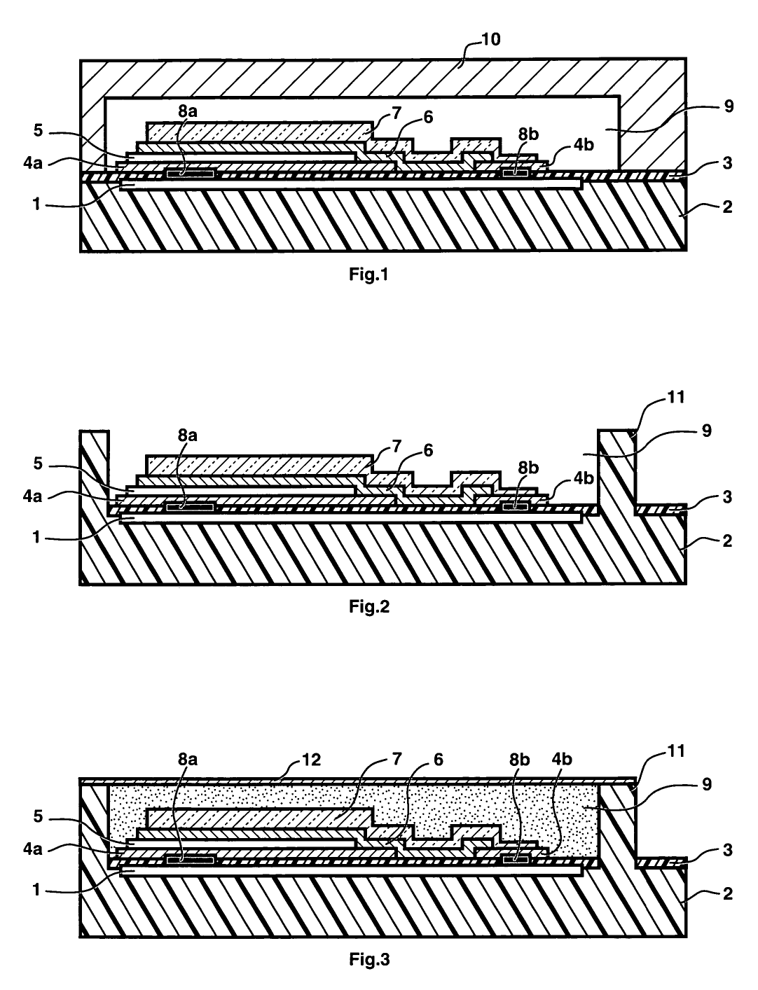

FIG. 1 represents a component wherein a power source is formed on an integrated circuit 1 itself formed on an insulating substrate 2. The power source is designed to supply at least a part of the elements of the integrated circuit 1. In an alternative embodiment (not shown) the power source and integrated circuit are arranged side by side on the substrate 2. When the power source is formed on the integrated circuit, the top layer of the integrated circuit can act as substrate therefor. The topology (uneven surface) and/or density of the top layer of the integrated circuit may however be unsuitable for achieving additional layers presenting the electrical properties required for the power source. In a preferred embodiment, an intermediate insulating layer 3 is deposited on the integrated circuit and acts as substrate supporting the different elements of the power source. The intermediate insulating layer 3 deposited on the integrated circuit is sufficiently thick to be able to be flattened on its top face if necessary, before the power source is formed, The intermediate insulating layer can be made of mineral material (glass, SiO₂, etc . . . ) or organic material (polymer, epoxy, etc . . . ). Flattening thereof can be achieved by mechanical or mechano-chemical means (by polishing, for example). A flat intermediate insulating layer can also be obtained directly if it is formed on the integrated circuit by liquid means. The flat intermediate insulating layer 3 preferably covers the whole of the integrated circuit 2 and substrate 1 (FIG. 1). The power source is then fabricated on the intermediate insulating layer 3 which acts as substrate therefor.

The substrate 2, made of any suitable known material, can notably be a silicon, glass, plastic substrate, etc. The integrated circuit 1 is also made in known manner, by any type of technology used for fabrication of integrated semi-conductors.

The power source can be formed by a micro-battery the thickness whereof is comprised between 7 μm and 30 μm (preferably about 15 μm), for example a lithium micro-battery formed by conventional chemical vapor deposition (CVD) or physical vapor deposition (PVD) techniques. Such a micro-battery, in the form of thin films, is notably described in documents WO-A-98/48467 and U.S. Pat. No. 5,561,004.

The operating principle of a micro-battery is based, in known manner, on insertion and de-insertion of an alkaline metal ion or a proton in a positive electrode of the micro-battery, preferably a lithium ion Li+originating from a metallic lithium electrode. The micro-battery is formed by a stack of layers obtained by CVD or PVD, respectively constituting two current collectors 4a and 4b, a positive electrode 5, an electrolyte 6, and a negative electrode 7.

Connecting pads 8a and 8b of the integrated circuit 1, equipping the top part of the integrated circuit, pass through the intermediate insulating layer 3 to come into contact with the current collectors 4a and 4b constituting the connecting pads of the micro-battery. The electrical connections between the integrated circuit and the micro-battery are thus achieved by the metallic contact between the associated layers forming the connecting pads. The power source formed by the micro-battery can thus supply at least a part of the elements of the integrated circuit 1 whereon it is formed.

The elements of the micro-battery 1 can be made of various materials:
The metal current collectors 4a and 4b can for example be platinum (Pt), chromium (Cr), gold (Au) or titanium (Ti) based.
The positive electrode 5 can be formed by LiCoO₂, LiNiO₂, LiMn₂O₄, CuS, CuS₂, WO_{y}S_{z}, TiO_{y}S_{z}, V₂O₄ or V₃O₈ and lithium forms of these vanadium oxides and metal sulphides.
The electrolyte 6, which is a good ion conductor and electric insulator, can be formed by a vitreous material with a boron, lithium oxide or lithium salt base.
The negative electrode 7 can be formed by metallic lithium deposited by thermal evaporation, by a lithium-based metal alloy or by an insertion compound of SiTON, SnNₓ, InNₓ, SnO₂, etc. type.

Depending on the materials used, the operating voltage of a micro-battery is comprised between 2V and 4V, with a surface capacity of about 100 μAh/cm². Recharging of a micro-battery only requires a few minutes charging.

It may be indispensable to protect the component, and more particularly the power source, from the ambient environment. Certain elements comprised in the composition of a micro-power source are in fact sensitive to the atmospheric conditions. The metallic lithium constituting the negative electrode of the micro-batteries, in particular, oxidizes quickly in contact with air, in particular in the presence of humidity.

The type of coating described in U.S. Pat. No. 5,561,004 to protect a lithium battery achieved in the form of thin films from the outside atmosphere provides chemical protection of the battery, but does not provide protection of the component against an intrusion of mechanical type.

According to the invention, the component comprises a sealed cavity 9 wherein the parts of the component to be protected, i.e. at least the power source, are arranged. In FIGS. 1 to 3, the power source and integrated circuit 1 are completely housed in the cavity 9. The integrated circuit and power source can be arranged separately or in the form of an assembly in the cavity 9, but are preferably fabricated directly in the cavity, the bottom whereof acts as substrate.

In a first embodiment, represented in FIG. 1, the cavity 9 is closed by a cover 10 that is fitted over the elements to be protected, more particularly over the micro-battery. The cover is preferably formed by a silicon, metal, polymer, epoxy or glass plate wherein the cavity 9 is etched. The cover 10 is fixed onto the substrate 2 or onto the intermediate plate 3 acting as substrate for the micro-battery so as to surround the parts of the component to be protected. In FIG. 1, the cavity 9 is thus bounded by the cover and by the intermediate plate 3. Connecting pads other than pads 8a and 8b can be provided on the outside.

Assembling can be performed by any suitable means enabling tightness of the cavity 9 to be achieved, in particular by sticking or by anodic bonding (“Anodic bonding below 180° C. for packaging and assembling of MEMS using lithium”, Shuichi Shoji, D.E.C.E., Waseda University, 3-4-1, ohkubo, Shinjuku, Tokyo 169, 1997, IEEE). Sticking can be achieved by means of a polymer or epoxy glue or a photosensitive resin deposited beforehand on at least one of the surfaces to be assembled. According to another assembling alternative, sticking can be achieved by means of a fusible material such as fusible glass deposited in the form of a bead or a thin layer or a eutectic metal (indium or lead-tin alloy, for example) whose melting temperature is lower than that of lithium.

Assembling the cover 10 on the substrate 2 or on the intermediate insulating layer 3 is preferably performed in a vacuum or in an inert gas (argon or nitrogen, for example) so that the power source is in a sealed cavity having a neutral or protective atmosphere. In case of intrusion or attempted intrusion, the inert gas which may be contained in the cavity escapes and the ambient atmosphere enters the cavity 9 and comes directly into contact with the parts to be protected. As the power source is constituted by very reactive materials such as lithium which reacts to the humidity of air, any attempted intrusion into the component resulting in these materials coming into contact with the atmosphere causes immediate destruction of the power source and consequently makes the component inoperative, which enhances the security against an unauthorized user attempting to access the integrated circuit. Integrating a power source on the same substrate as an integrated circuit which it at least partly supplies essentially has the object of securing the integrated circuit. In the case of a smart card for example, the power source can be used to store sensitive information such as a confidential code in a memory. Destruction of the power source in the event of an intrusion deletes this information making the card tamper-proof and subsequent use thereof impossible.

In a second embodiment, represented in FIG. 2 before the cover 9 is closed, the cavity 9 is bounded laterally by a wall 11 surrounding all the parts to be protected, the height of the wall 11 being greater than the thickness of the parts to be protected. In a first alternative embodiment, the wall 11, made of glass, is formed on the substrate 2 by serigraphy, by injection of powders and precursors by means of an injector of the automobile injector type, by injection by means of micro-injectors of the type used in printer heads, by deposition of a glass or resin bead by photolithography or by injection, or by etching of a thick layer. In a second embodiment, the cavity is achieved by etching of the substrate 2, the integrated circuit 1 and power source then being embedded in the substrate 2. The cavity 9 can be closed in tightly sealed manner by a cover fixed onto the wall 11 and formed by a plate of the same type as the cover 10 described above.

In another embodiment, represented in FIG. 3, the cavity 9 is filled with a filling material designed to enhance protection and consisting of silicone resin, thermosetting resin, polymer, epoxy, fusible glass or a metal chosen from indium, tin, lead or alloys thereof. To achieve a better sealing, the filled cavity 9 can in addition be covered by an additional protective coating 12. The latter can be formed by a thin, metallic or insulating layer obtained by deposition (for example by CVD or PVD) or by sticking of a thin metallic strip.

The power source must supply sufficient power to perform a limited number of operations during the lifetime of the component while having as small dimensions as possible, compatible with the dimensions of integrated circuits, in particular with their thickness (a few tens to a few hundreds of microns).

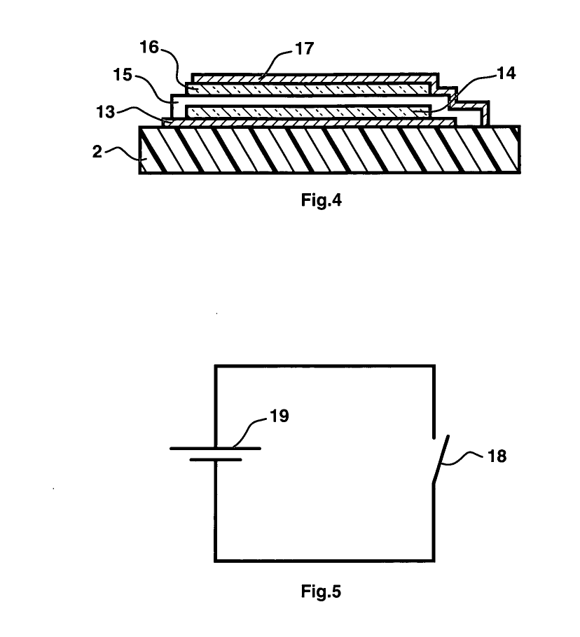

A micro-supercapacitance can constitute another suitable power source. Such a supercapacitance is achieved in the form of thin films with the same type of technology as micro-batteries. As represented in FIG. 4, it is formed by stacking, on an insulating substrate 2 preferably made of silicon, of layers respectively constituting a bottom current collector 13, a bottom electrode 14, an electrolyte 15, a top electrode 16 and a top current collector 17.

The elements of the micro-supercapacitance can be made of different materials. The electrodes 14 and 16 can have a base formed by carbon or metal oxides such as RuO₂, IrO₂, TaO₂ or MnO₂. The electrolyte 15 can be a vitreous electrolyte of the same type as that of the micro-batteries. The micro-supercapacitance can have a surface capacity of about 10 μAh/cm² and full charge thereof can be achieved in less than one second.

A particular embodiment of a micro-supercapacitance able to be used in a component according to the invention is represented in FIG. 4. The micro-supercapacitance is formed on the insulating silicon substrate 2. It is formed in five successive deposition steps:
In a first step, the bottom current collector 13 is formed by deposition of a layer of platinum with a thickness of 0.2±0.1 μm, by radiofrequency cathode sputtering.
In a second step, the bottom electrode 14, made of ruthenium oxide (RuO₂), is fabricated from a metallic ruthenium target, by reactive radiofrequency cathode sputtering in a mixture of argon and oxygen (Ar/O₂) at ambient temperature. The layer formed has a thickness of 1.5±0.5 μm.
In a third step, a layer with a thickness of 1.2±0.4 μm constituting the electrolyte 15 is formed. This is a conducting glass of Lipon type (Li₃PO_{2.5}NO_{0.3}) obtained by cathode sputtering under partial nitrogen pressure with a Li₃PO₄ or 0.75(Li₂O)−0.25(P₂O₅) target.
In a fourth step, the top electrode 16, made of ruthenium oxide (RuO₂), is fabricated in the same way as the bottom electrode 14 during the second step.
In a fifth step, the top current collector 17, made of platinum, is formed in the same way as the bottom current collector 13 during the first step.

Securing of the component can be further enhanced when the cavity 9 is not filled with a filling material, by fitting a pressure sensor inside the cavity 9. The pressure sensor detects any pressure variation inside the cavity and makes the component inoperative when the pressure variation exceeds a predetermined threshold. The internal pressure of the cavity, whether it be lower (vacuum) or higher than atmospheric pressure, is liable to vary with time according to the quality of assembly (leakage, etc.). Its evolution with time cannot be foreseen and cannot be measured from outside. The internal pressure of the cavity thus constitutes a tamper-proof code. Such a protection makes an intrusion performed in a controlled and inert atmosphere ineffective.

In the embodiment illustrated in FIG. 5, a normally open switch 18 is connected in parallel to the power source 19. The switch 18 is automatically closed by the pressure sensor when the pressure variation exceeds the predetermined threshold, then short-circuiting the power source 19 which discharges immediately causing the component to be rendered inoperative. The switch 18 can for example be formed by a membrane of the pressure sensor, one face whereof is subjected to atmospheric pressure in case of deterioration of the cavity and movement whereof causes short-circuiting of the power source.

In an alternative embodiment, not shown, the pressure sensor is supplied by the power source and managed by the integrated circuit 1. The integrated circuit 1 periodically reads the pressure value measured by the pressure sensor and detects, by differential comparison, any leak of the cavity or any ill-intentioned intrusion. When the pressure variation exceeds the predetermined threshold, the integrated circuit 1 renders the component inoperative, for example by discharging the power source via an electronic switch formed by a transistor. The frequency of measurement of the pressure in the cavity is adjusted so as to make any intrusion into the component impossible, while limiting the power consumption.

1. A micro- or nano-electronic component comprising a power source in the form of thin films deposited on a substrate and means for protecting the power source against the ambient atmosphere, component characterized in that the protection means comprise a sealed cavity (9) wherein the unprotected power source is arranged, any penetration of the ambient atmosphere into the sealed cavity causing destruction of the power source by oxidation, thereby making the component inoperative.

2. Component according to claim 1, characterized in that the cavity (9) is filled with an inert gas.

3. Component according to claim 1, characterized in that the inside of the cavity (9) is in a vacuum.

4. Component according to claim 2, characterized in that it comprises a pressure sensor arranged inside the cavity and detecting a pressure variation inside the cavity to make the component inoperative when the pressure variation exceeds a predetermined threshold.

5. Component according to claim 4, characterized in that the pressure sensor short-circuits the power source (19) when the pressure variation exceeds the predetermined threshold.

6. Component according to claim 1, characterized in that the cavity (9) is closed by a cover (10).

7. Component according to claim 6, characterized in that the cover (10) is formed by a silicon, metal, polymer, epoxy or glass plate.

8. Component according to claim 7, characterized in that the cavity (9) is etched in the cover (10).

9. Component according to claim 6, characterized in that the cover (10) is fixed by sticking.

10. Component according to claim 1, characterized in that the cavity (9) is filled with a filling material consisting of silicone resin, thermosetting resin, polymer, fusible glass or a metal chosen from indium, tin, lead or alloys thereof.

11. Component according to claim 10, characterized in that the filled cavity (9) is covered by a protective coating (12).

12. Component according to claim 11, characterized in that the protective coating (12) is constituted by a thin layer formed by semi-conductor fabrication techniques.

13. Component according to claim 11, characterized in that the protective coating (12) is constituted by a thin metallic strip stuck onto the filled cavity.

14. Component according to claim 1, characterized in that the cavity (9) is formed by etching in the substrate (2), the power source being formed on the bottom of the cavity.

15. Component according to claim 1, characterized in that the cavity (9) is bounded laterally by a wall (11) surrounding all the parts to be protected, the height of the wall being greater than the thickness of the parts to be protected.

16. Component according to claim 15, characterized in that the wall (11) is formed by serigraphy on the substrate.

17. Component according to claim 15, characterized in that the wall (11) is formed by injection on the substrate.

18. Component according to claim 15, characterized in that the wall (11) is formed by photolithography on the substrate.

19. Component according to claim 1, characterized in that the power source is formed by a micro-battery.

20. Component according to claim 1, characterized in that the power source is formed by a micro-supercapacitance.
